(19) United States
(12) Patent Application Publication
(10) Pub. No.: US 2007/0146011 A1
(43) Pub. Date: Jun. 28, 2007

(54) Duty cycle adjustment

(76) Inventors: Frank P. O'Mahony, Portland, OR (US); Bryan K. Casper, Hillsboro, OR (US); James E. Jaussi, Hillsboro, OR (US); Moonkyun Maeng, Folsom, CA (US)

Correspondence Address: INTEL CORPORATION;c/o INTELLEVATE, LLC, P.O. BOX 52050, MINNEAPOLIS, MN, 55402, US

(21) Appl. No.: 11/321,371

(22) Filed: Dec. 28, 2005

(51) Int. Cl. H03K 19/00

(52) U.S. Cl. 326/93

(57) ABSTRACT

Disclosed herein are duty cycle adjustment circuits to control the duty cycle in a clock signal. In some embodiments, a circuit is provided comprising a clock driver to drive a differential clock signal through a clock path. A feedback circuit is coupled (i) to the clock path to monitor offset in the clock signal, and (ii) to the clock driver to digitally control the clock driver offset based on the monitored clock signal offset. Other embodiments are disclosed herein.

### BACKGROUND

With integrated circuit (IC) devices, clock signals with well controlled duty cycles (the relative amount of time the clock is High versus Low in each cycle) may be important to system performance. A good example is in data communication applications where both edges of the clock may be used to sample data. In some cases, when clock edges are not evenly spaced (50% duty cycle), there can be a reduction in timing margin resulting in lower data rates. In other cases, a non 50% (but controlled) duty cycle may be desired to achieve optimal system performance. Another example is with a sequential logic circuit operating on both the rising and falling edges of a clock. With such circuits, duty-cycle error can lead to min-path or max-path violations.

Duty-cycle error can be attributed to a variety of factors such as offset error resulting from systematic offset and offset due to variations in process, voltage, and/or temperature. To maintain an acceptable duty cycle, many systems employ some type of offset control.

With reference to FIG. 1, a conventional clock driver circuit 100 with duty cycle control via offset control is shown. It includes a clock driver 102 and a feedback circuit comprising a feedback amplifier 104 and a low pass filter 106. The clock driver 102 comprises a differential amplifier with an input (CLK IN) to receive a differential clock signal and provide an amplified version of it at its output (CLK OUT). The feedback amplifier 104 and low pass filter 106 are coupled between the output of the clock driver 102 and an analog input of the clock driver 102 to controllably vary the offset in the clock driver 102. The feedback amplifier 104 samples the clock signal, and the low pass filter 106 derives from it the common mode offset level. It provides an inverted form of this offset to an analog offset control input of the clock driver 102 to reduce (e.g., minimize or zero) the offset in the clock signal. Unfortunately, offset in the feedback path is not addressed and thus can lead to duty-cycle errors in the outputted clock signal. Another problem is that the offset control signal is analog, which in a noisy environment, can limit the achievable separation distance between the feedback circuit and clock driver. Accordingly, an improved solution is desired.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a schematic diagram of a conventional duty cycle adjustment circuit.

FIG. 2 is a schematic diagram of a duty cycle adjustment circuit with a variable offset driver in accordance with some embodiments.

FIG. 3 is a schematic diagram of a duty cycle adjustment circuit with a variable offset driver in accordance with some embodiments.

FIG. 4 is a schematic diagram of a duty cycle adjustment circuit in accordance with some embodiments.

FIG. 5 is a block diagram of a computer system with at least one I/O interface having a duty cycle adjustment circuit in accordance with some embodiments.

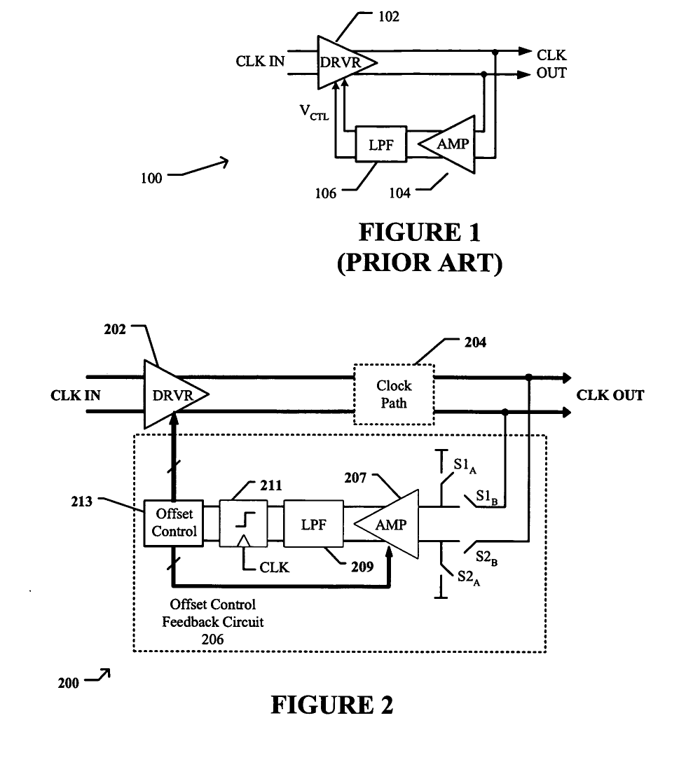

### DETAILED DESCRIPTION

FIG. 2 shows a clock driver circuit 200 with duty cycle control in accordance with some embodiments. Clock driver circuit 200 generally comprises a clock driver 202, a clock path 204, and a feedback circuit 206. The clock driver 202 comprises a differential amplifier with a digitally controllable, variable offset. For example, it could be implemented with a differential amplifier having an analog controlled variable offset and a D to A converter to digitally control the analog offset control.

The clock driver 202 drives a differential clock signal from its input (CLK IN) through the clock path 204 to an output (CLK OUT). The clock path 204 represents the physical path from the clock driver to the output (CLK OUT). It may correspond to any type of clock signal pathway such as from a pair of relatively short conductor traces to conductors, buffers, and/or other digital blocks cascaded together between the clock driver 202 and clock output (CLK OUT). Furthermore, the clock path may span over relatively long distances or be localized and/or used in an isolated environment.

The feedback circuit 206 is coupled between the clock output and the digital, offset control input of the clock driver 202 to reduce the common mode offset of the clock signal at the clock output (CLK OUT). In the depicted embodiment, it comprises a differential amplifier 207 (with digitally controllable variable offset), a low pass filter 209, a digital slicer 211, and an offset control circuit 213, coupled together as indicated, with separate digital offset control signals provided from outputs of the offset control circuit 213 to the clock driver 202 and feedback amplifier 207. The feedback circuit 206 also comprises switches S1_{A}, S2_{A}, S1_{B}, and S2_{B} to switch the feedback circuit between a feedback circuit calibration mode (mode A) and a clock driver calibration mode (mode B).

The feedback amplifier 207 comprises a differential amplifier for measuring offset in the clock signal. It may be the same type of amplifier used for the clock driver 202, or it may comprise a different (e.g., smaller and/or reduced bandwidth) amplifier. The low pass filter 209 comprises a filter (e.g., simple RC filter) to filter out higher frequency components (including possibly high-frequency clock pulses if the feedback circuit is active while the clock driver is in operation) and pass through to the slicer 211 the common mode offset of the clock signal from the feedback amplifier 207. It may be formed separately from the feedback amplifier 207 or integrated within it.

The slicer 211 digitizes and latches the offset signal from the low pass filter 209 and provides the digital error signal to the offset control circuit 213. In the depicted embodiment, it operates from a clock signal that preferably is suitably slower than the clock to be driven through the clock driver 202. It may be implemented with any suitable circuit such as a comparator, latch, flip-flop or the like. The offset control circuit 213 integrates (or accumulates) the clocked bit values from the slicer 211 to provide an appropriate offset control signal to either the clock driver 202 or feedback amplifier 207 (depending on the activated mode). It may be implemented with any suitable logic such as a finite state machine or discrete logic components, for example, to implement a counter, control logic, and output latches to provide digital offset signals (e.g., 4-bit words) to the clock driver 202 and feedback amplifier 207.

The feedback circuit 206 has two modes of operation: feedback calibration (mode A) and clock driver calibration (mode B). Note that the feedback circuit 206 may be inactive when the clock driver 202 is in operation. That is, the loop can either be shut off after the clock driver and feedback amplifier offsets have been determined, which is useful for compensating for static offsets such as device variations and power savings, or it can continue to run to track time-varying offsets in the circuit while the clock driver 202 is driving a clock signal through the clock path 204. Regardless of whether the feedback circuit is operating, however, latched offset control words should remain applied at the clock driver and feedback amplifier. The latches used to provide the offset values may reside in the offset control circuit 213 or in the clock driver and feedback amplifier themselves.

During the feedback calibration mode, switches S1_{A} and S2_{A} are closed, while S1_{B} and S2_{B} are opened, which causes offset in the feedback amplifier 207 to be detected and corrected. The inputs to the feedback amplifier 207 are shorted to VCM, which is a DC voltage that corresponds to the common-mode level of the clock signal at CLK OUT essentially shorting the inputs together. Since the feedback amplifier 207 has inherent offset, its output will be non-zero. This offset level is filtered (although the filter is not required) and converted to a digital level by the slicer 211. The offset control circuit 213 determines the offset control word based on slicer output values over time and provides the control word to the feedback amplifier 207. That is, as long as the slicer 211 indicates that offset is positive (e.g., outputting a ‘1), it may count “up” to increase the opposing offset generated in the amplifier 207. When the slicer error bit is ‘0, it knows that the offset is zero or negative and can thus hold the offset control word at its present value or decrement it. Any suitable algorithm for maintaining a suitably stable control word can be used. For example, the word may be allowed to dither when the error bit Vass elates between ‘1 and ‘0 or a different scheme to inhibit dithering could be used.

Once the offset code is determined and applied to the feedback amplifier 207, the feedback circuit can then switch to clock driver calibration mode. The “A” switches are opened and the “B” switches are closed connecting the output clock signal (at CLK OUT) to the feedback amplifier 207. With offset error now reduced (or even “zeroed”) in the feedback amplifier 207, the feedback circuit operates, as just described with respect to feedback calibration, but now to reduce offset in the clock driver 202 and clock path 204. It applies a compensating offset control word at the clock driver 202 based on offset monitored from the clock output. Once this offset is sufficiently reduced (with the offset control word applied at the clock driver 202), the clock driver 202 is operated to drive the clock signal from the clock input (CLK IN) to the clock output (CLK OUT).

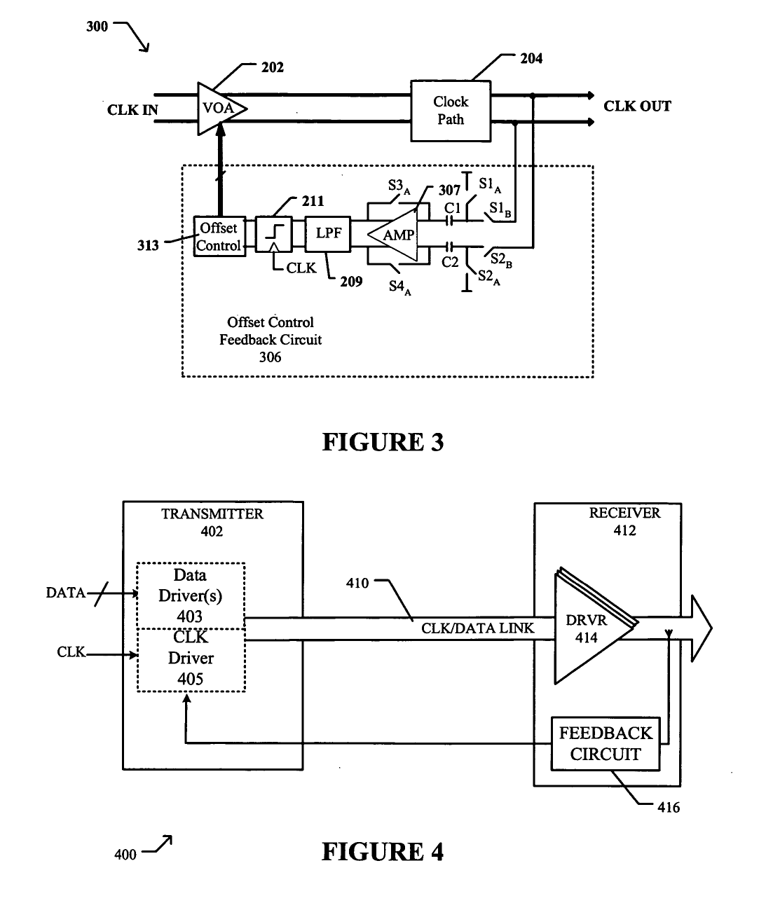

FIG. 3 shows another clock driver circuit 300, which is a variation of the clock driver circuit of FIG. 2. However, instead of using a digitally controlled offset control scheme for the feedback offset control mode, the feedback circuit uses a conventional analog auto-zeroing circuit formed from capacitors C1, C2 and switches S1_{A}-S4_{A}, and S1_{B}, S2_{B}. The rest of the feedback circuit may be the same, using the slicer 211 and offset control circuit 213 to apply a digital offset control word to the clock driver 202.

During the feedback calibration mode (mode “A”), switches S1A-S4A are closed and S1B and S2B are opened. This causes the differential outputs of the feedback amplifier 307 to be shorted to the inputs (in an inverse configuration). As a result, the differential voltage imposed at capacitors C1, C2 across the differential amplifier input roughly equals the negative voltage of the amplifier offset. Thus, when the amplifier is operated during the clock driver calibration mode (“A” switches opened and “B” switches closed), the negative offset level stored across the capacitors is applied at the amplifier inputs to “zero” out its offset. This embodiment may be useful when it is desirable to continuously track and calibrate the clock driver offset.

FIG. 4 shows a block diagram of a point to point communications system 400 for transmitting data over a remote link (e.g., relatively long or noisy channel within a chip or with a chip-to-chip link. It generally comprises a transmitter 402, with one or more data drivers 403 and possibly a clock driver 405, to transmit data and clock signals over a clock/data link 410 to a receiver 412. (In some embodiments, only data may be transmitted such as in a clock data recovery [CDR] system where the clock is actually embedded in the data signal.) The clock/data link 410 may comprise a plurality of channels such as differential channels to convey differential data and clock signals, e.g., in a source synchronous scheme. The receiver 412 comprises drivers (clock and data) 414 and a feedback circuit coupled between at least one of the drivers 414 and a clock driver 405 to control clock duty cycle based on a monitored parameter at the receiver 412. The monitored parameter may comprise any suitable parameter that is indicative of clock duty cycle such as offset in a clock signal or overall system performance such as voltage margin, timing margin, or bit error rate in a data signal.

The feedback circuit may comprise any suitable circuit to convert the monitored parameter to a digital duty cycle control (e.g., offset control signal) to send back (e.g., over a digital back channel) to the clock driver in the transmitter. If the monitored parameter is clock signal offset, a feedback circuit such as in FIG. 2 or 3 could be used. The use of a digital feedback correction signal allows the duty cycle detection/control (feedback circuit) part of the loop to be physically remote from the transmitter providing for a “global” duty cycle correction scheme spanning relatively large physical distances. This can be a useful feature because the effects of both lossy channels and unknown duty-cycle error introduced by the clock transmitter can be accounted for within the duty-cycle control loop.

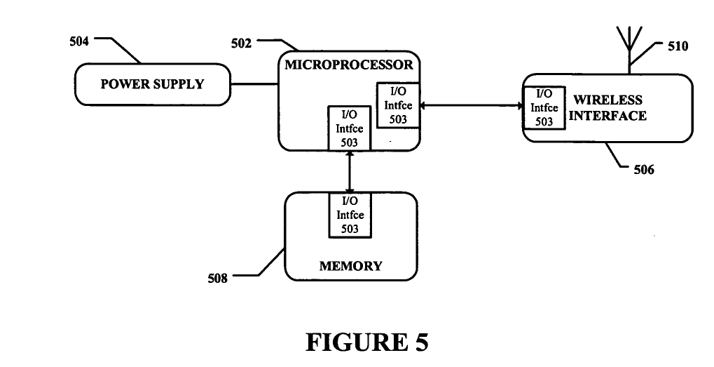

With reference to FIG. 5, one example of a computer system is shown. The depicted system generally comprises a processor 502 that is coupled to a power supply 504, a wireless interface 506, and memory 508. It is coupled to the power supply 504 to receive from it power when in operation. The wireless interface 506 is coupled to an antenna 510 to communicatively link the processor through the wireless interface chip 506 to a wireless network (not shown). The microprocessor 502, memory 508, and wireless interface 506 comprise I/O interfaces 503 to implement point-to-point communication links between the respective chips as indicated. At least one of the I/O interface circuits 503 comprises a duty cycle control circuit in accordance with an embodiment disclosed herein.

It should be noted that the depicted system could be implemented in different forms. That is, it could be implemented in a single chip module, a circuit board, or a chassis having multiple circuit boards. Similarly, it could constitute one or more complete computers or alternatively, it could constitute a component useful within a computing system.

The invention is not limited to the embodiments described, but can be practiced with modification and alteration within the spirit and scope of the appended claims. For example, it should be appreciated that the present invention is applicable for use with all types of semiconductor integrated circuit (“IC”) chips. Examples of these IC chips include but are not limited to processors, controllers, chip set components, programmable logic arrays (PLA), memory chips, network chips, and the like.

Moreover, it should be appreciated that example sizes/models/values/ranges may have been given, although the present invention is not limited to the same. As manufacturing techniques (e.g., photolithography) mature over time, it is expected that devices of smaller size could be manufactured. In addition, well known power/ground connections to IC chips and other components may or may not be shown within the FIGS. for simplicity of illustration and discussion, and so as not to obscure the invention. Further, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., circuits) are set forth in order to describe example embodiments of the invention, it should be apparent to one skilled in the art that the invention can be practiced without, or with variation of, these specific details. The description is thus to be regarded as illustrative instead of limiting.

What is claimed is:

1. A circuit, comprising:
a clock driver to drive a differential clock signal through a clock path, the clock driver having a digitally controllable offset; and
a feedback circuit coupled (i) to the clock path to monitor offset in the clock signal, and (ii) to the clock driver to digitally control the clock driver offset based on the monitored clock signal offset.

2. The circuit of claim 1, in which the clock path comprises one or more buffers ahead of the feedback circuit.

3. The circuit of claim 1, in which the feedback circuit comprises a feedback amplifier with an offset reducing circuit to reduce offset in the feedback amplifier.

4. The circuit of claim 3, in which the offset reducing circuit comprises an analog zeroing circuit coupled to the feedback amplifier to provide it with an analog offset compensating signal.

5. The circuit of claim 3, in which the offset reducing circuit comprises a slicer and digital logic to provide the feedback amplifier with a digital control signal to reduce its offset.

6. The circuit of claim 5, in which the slicer and digital logic are also coupled to the clock driver to digitally control its offset.

7. The circuit of claim 1, in which the feedback circuit is to be off chip from the clock driver.

8. The circuit of claim 1, in which the feedback circuit is to be inactive during an operating mode of the first clock driver.

9. A circuit, comprising:
a clock driver to transmit a clock signal to a remote receiver to transmit data to the receiver, the clock driver to control the duty cycle; and
a feedback circuit to provide a digital control signal to the clock driver to control the duty cycle based on a signal parameter at the receiver.

10. The circuit of claim 9, in which the clock driver comprises a variable offset differential amplifier with a digitally controllable offset to control the duty cycle.

11. The circuit of claim 10, in which the remote receiver is in a different chip from the clock driver.

12. The circuit of claim 9, in which the receiver signal parameter comprises a voltage offset of the clock signal.

13. The circuit of claim 9, in which the receiver signal parameter comprises a voltage margin in a received data signal.

14. A circuit, comprising:
a clock driver to drive a differential clock signal through a clock path, the clock driver having a digitally controllable offset; and
a feedback circuit coupled (i) to the clock path to monitor offset in the clock signal, and (ii) to the clock driver to digitally control the clock driver offset based on the monitored clock signal offset, the feedback circuit comprising a feedback amplifier with an offset reducing circuit to reduce offset in the feedback amplifier.

15. The circuit of claim 14, in which the clock path comprises one or more buffers ahead of the feedback circuit.

16. The circuit of claim 14, in which the offset reducing circuit comprises an analog zeroing circuit coupled to the feedback amplifier to provide it with an analog offset compensating signal.

17. The circuit of claim 14, in which the offset reducing circuit comprises a slicer and digital logic to provide the feedback amplifier with a digital control signal to reduce its offset.

18. The circuit of claim 17, in which the slicer and digital logic are also coupled to the clock driver to digitally control its offset.

19. A system, comprising:
(a) a microprocessor comprising:
(i) a clock driver to drive a differential clock signal through a clock path, the clock driver having a digitally controllable offset; and
(ii) a feedback circuit coupled (1) to the clock path to monitor offset in the clock signal, and (2) to the clock driver to digitally control the clock driver offset based on the monitored clock signal offset, the feedback circuit comprising a feedback amplifier with an offset reducing circuit to reduce offset in the feedback amplifier;
(b) an antenna; and
(c) a wireless interface coupled to the microprocessor and to the antenna to communicatively link the microprocessor to a wireless network.

20. The system of claim 19, in which the microprocessor is coupled to a battery to supply it with power.
